(19) United States
(12) Patent Application Publication
(10) Pub. No.: US 2014/0178823 A1
(43) Pub. Date: Jun. 26, 2014

(54) PHOTOSENSITIVE POLYIMIDE AND NEGATIVE TYPE PHOTORESIST COMPOSITION CONTAINING THE SAME

(71) Applicant: INDUSTRIAL TECHNOLOGY RESEARCH INSTITUTE, Hsinchu (TW)

(72) Inventors: Chen-Lung LIN, Hsinchu City (TW); Fu-Shun HSU, Baozhong Township (TW); Kuo-Chan CHIOU, Tainan City (TW)

(21) Appl. No.: 13/908,082

(22) Filed: Jun. 3, 2013

(30) Foreign Application Priority Data
Dec. 26, 2012 (TW) 101150036

(51) Int. Cl. G03F 7/038

(52) U.S. Cl. CPC G03F 7/0387
USPC 430/286.1; 528/185

(57) ABSTRACT

A photosensitive polyimide and negative type photo-resist composition containing the same are provided. The photosensitive polyimide is represented by formula (I):

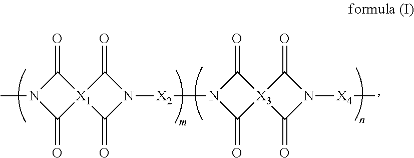

wherein X₁ and X₃ are the same or different organic functional groups having four covalent bonds; X₂ and X₄ are the same or different organic functional groups having two covalent bonds, and X₂ contains functional groups of OH or COOH and any one selected from the functional groups below:

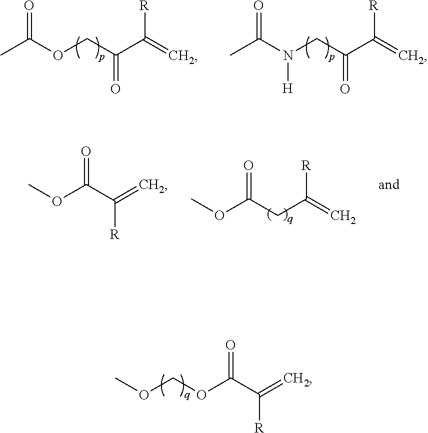

wherein R is H or CH₃, p and q are integers of 1 to 20, and m and n in formula (I) are numbers of repeat units.

### CROSS REFERENCE TO RELATED APPLICATIONS

This application claims priority of Taiwan Patent Application No. 101150036, filed on Dec. 26, 2012, the entirety of which is incorporated by reference herein.

### TECHNICAL FIELD

The disclosure relates to a photosensitive resin, and more particularly to a photosensitive polyimide.

### BACKGROUND

Polyimide (PI) is a commonly used polymer material with high performance due to its high heat resistance, excellent chemical resistance, electric insulativity, and high mechanical strength. The chemical structure of polyimide does not have any photosensitive functional group. Thus, while polyimide is applied to a photoresist material, an additional functional group which can help polyimide to perform a photosensitive reaction needs to be introduced into the polyimide. A common method is the use of an acrylic functional group to bond with a precursor of polyimide, i.e. polyamide acid (PAA) by a covalent bonding method. Then, a photosensitive precursor of polyimide is obtained by this method.

Another method is the use of a tertiary amine to perform acid-base neutralization with an acid functional group, i.e. —COOH of a precursor of polyimide, i.e. polyamide acid (PAA) to form an ionic bonding. Then, a photosensitive precursor of polyimide is obtained by this method.

However, when the photosensitive precursors of polyimide obtained by the two methods described above are used to make a photoresist material, the photoresist material needs a hard baking step performed at a temperature of above 300° C. or even 350° C. during an end process of line to ensure the photosensitive precursors of polyimide, which have been exposed to light, perform a ring-closure reaction to form polyimide.

Currently, developments in the semiconductor industry, photoelectrical industry, and flexible printed circuit board industry are moving toward reducing process temperatures. However, the photoresist material formed from the above mentioned conventional photosensitive precursor of polyimide needs a process temperature of higher than 300° C., which can not satisfy the requirement of reducing process temperatures. Moreover, a copper foil substrate is easily oxidized at a process temperature higher than 300° C.

Therefore, it is important to develop a polyimide which can be used in a low-temperature process.

### SUMMARY

According to an embodiment of the present disclosure, a photosensitive polyimide of Formula (I) is provided:

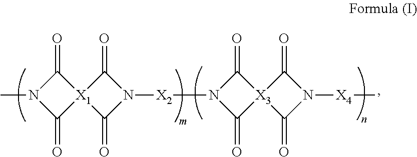

wherein X₁ and X₃ are the same or different organic functional groups having four covalent bonds;
X₂ and X₄ are the same or different organic functional groups having two covalent bonds, and wherein X₂ is a combination of:

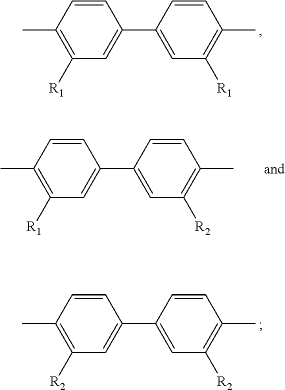

or a combination of:

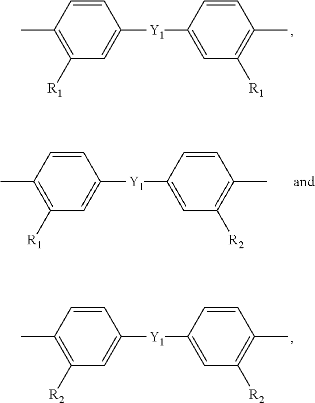

wherein Y₁ is selected from a group consisting of:
—O—, —CO—, —S—, —SO₂—, —C(CH₃)₂—, —C(CF₃)₂—, —(CH₂)ₙ₁—, —O(CH₂)ₙ₂O—, —COO(CH₂)ₙ₃OCO—,

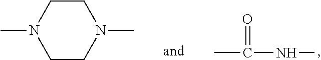

wherein n1, n2 and n3 are an integer of 1 to 10;

### R₁ is OH or COOH;

R₂ is selected from a group consisting of:

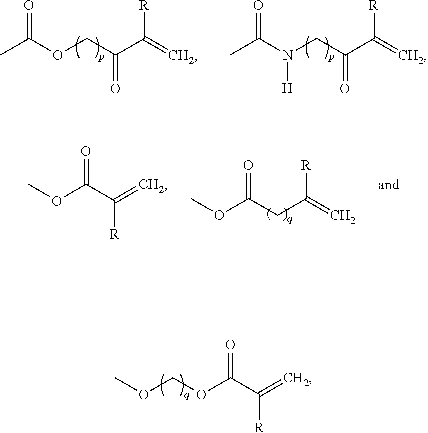

wherein R is H or CH₃, p is an integer of 1 to 20, and q is an integer of 1 to 20;
m and n in Formula (I) are the number of repeated units, wherein m is an integer of 10 to 1000, and n is an integer of 10 to 1000.

Furthermore, a negative type photoresist composition is provided. The negative type photoresist composition comprises: 100 parts by weight of a photosensitive polyimide at least including the photosensitive polyimide of Formula (I); 20 to 150 parts by weight of a photocrosslinking agent; and 0.01 to 20 parts by weight of a photoinitiator.

A detailed description is given in the following embodiments with reference to the accompanying drawings.

### BRIEF DESCRIPTION OF THE DRAWINGS

The disclosure can be more fully understood by reading the subsequent detailed description and examples with reference to the accompanying drawings, wherein:

FIG. 1 shows an analysis spectrum of a photosensitive polyimide of the embodiment 4 by a nuclear magnetic resonance (NMR).

### DETAILED DESCRIPTION

The following description is of the best-contemplated mode of carrying out the disclosure. The description is provided for illustrating the general principles of the disclosure and is not meant to be limiting. The scope of the disclosure is best determined by reference to the appended claims.

A precursor of polyimide, i.e. polyamide acid (PAA) is usually formed by a dianhydride monomer reacting with a diamine monomer. Then, polyamide acid (PAA) proceeds with a dehydration ring-closing reaction by a heating or a chemical method to obtain polyimide (PI). An embodiment of the disclosure provides a photosensitive polyimide of Formula (I):

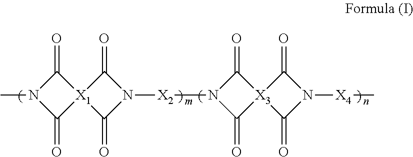

X₁ and X₃ in Formula (I) come from the dianhydride monomer. X₁ and X₃ may be the same or different organic functional groups having four covalent bonds. X₁ and X₃ are one functional group selected from the functional groups below:

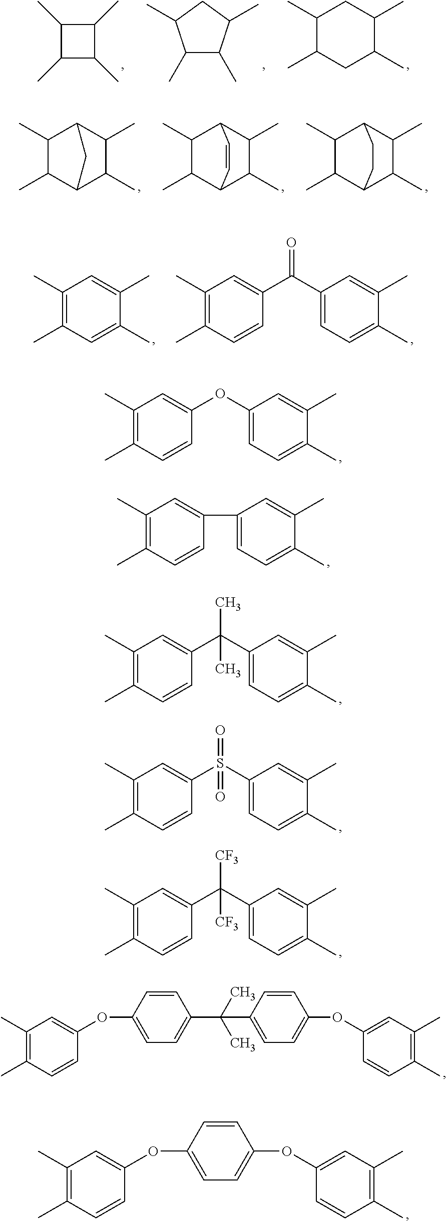

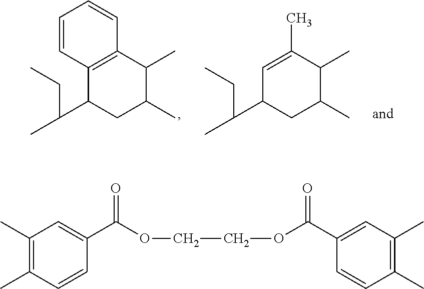

X2 and X4 in Formula (I) come from the diamine monomer. X₂ and X₄ may be the same or different organic functional groups having two covalent bonds, wherein X₂ is a combination of:

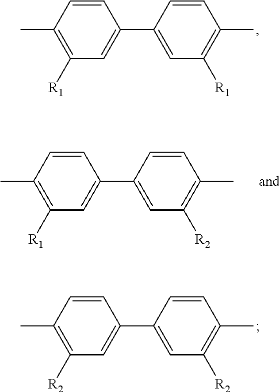

or a combination of:

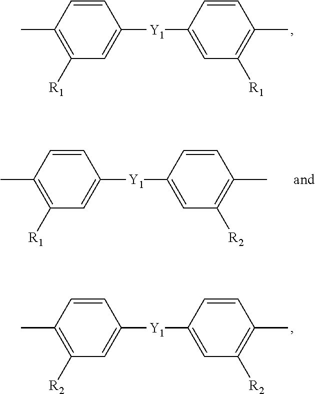

wherein Y is one functional group selected from the functional groups below: —O—, —CO—, —S—, —SO₂—, —C(CH₃)₂—, —C(CF₃)₂—, —(CH₂)ₙ₁—, —O(CH₂)ₙ₂O—, —COO(CH₂)ₙ₃OCO—,

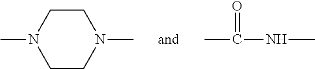

, wherein n1, n2 and n3 are an integer of 1 to 10;

### R₁ is OH or COOH;

R₂ is one functional group selected from the functional groups below:

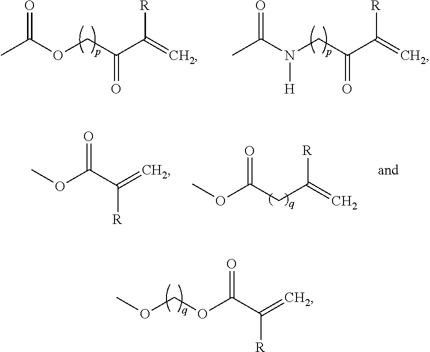

wherein R is H or CH₃, p is an integer of 1 to 20, and q is an integer of 1 to 20.

X₄ may be the same as X₂ in Formula (I), i.e. the photosensitive polyimide of Formula (I) may be polymerized from one kind of diamine monomer and other dianhydride monomers. Alternatively, X₄ can come from another diamine monomer which does not contain a OH or COOH functional group, i.e. the photosensitive polyimide of Formula (I) is polymerized from two kinds of diamine monomers and other dianhydride monomers. In which, X₄ may be one functional group selected from the functional groups below:

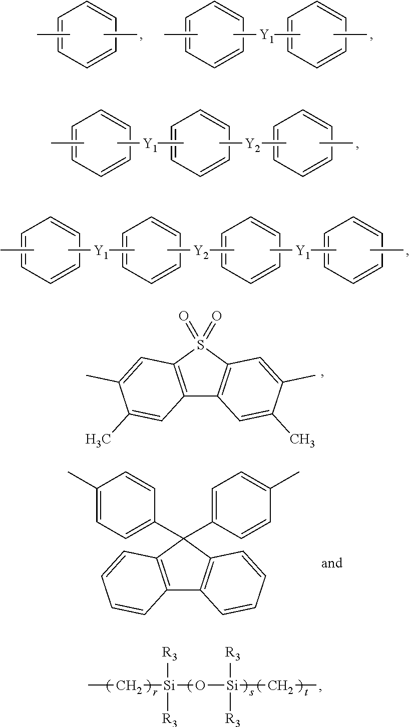

wherein Y1 and Y2 are the same or different organic functional groups having two covalent bonds, and Y₁ and Y₂ may be one functional group selected from the functional groups below:
—O—, —CO—, —S—, —SO₂—, —C(CH₃)₂—, —C(CF₃)₂—, —(CH₂)ₙ₁—, —O(CH₂)ₙ₂O—, —COO(CH₂)ₙ₃OCO—,

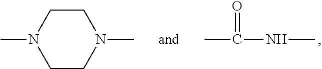

wherein n1, n2 and n3 are an integer of 1 to 10. R₃ is hydrogen, methyl, ethyl or phenyl; and r, s, t are an integer of 1 to 30.

When X₂ and X₄ in Formula (I) are different from each other and X₄ is one functional group selected from the functional groups described above, the mole ratio of the repeated units containing X₂ may be about 20 mol % to 85 mol %, and the mole ratio of the repeated units containing X₄ may be about 15 mol % to 80 mol % based on the total mole number of all repeated units in Formula (I).

The above-mentioned combinations of X₂ are obtained from the OH or COOH functional group of the diamine monomer reacting with an acrylic monomer. The acrylic monomer may be selected from a group consisting of 2-hydroxyethyl methacrylate (HEMA), acrylic acid (AA), methacrylic acid (MA), butyl acrylate (BA), acryloyl chloride (AC), etc.

The diamine monomers containing OH or COOH functional groups reacted with the dianhydride monomers and then proceeded with a dehydration ring-closing reaction to form polyimide. Next, the OH or COOH functional groups of polyimide reacted with the acrylic monomers to bond functional groups containing unsaturated double bonds onto polyimide. An example of the above described reaction is shown below:

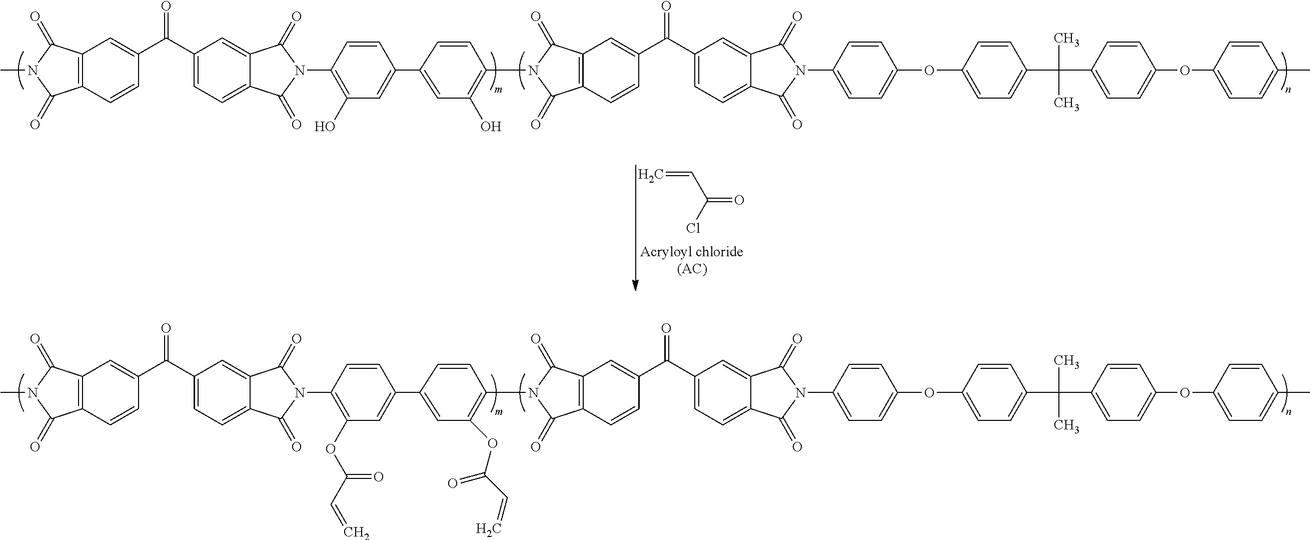

The acrylic monomer in the above reaction is acryloyl chloride (AC), and the above reaction is illustrated with an example in which all OH functional groups of polyimide reacted with the acrylic monomers to bond the functional groups containing unsaturated double bonds to form a photosensitive polyimide. However, in a practical example, the bonding ratio of the OH functional groups of polyimide bonded with the functional groups containing unsaturated double bonds will not reach 100%.

Another example of the reaction described above is shown below:

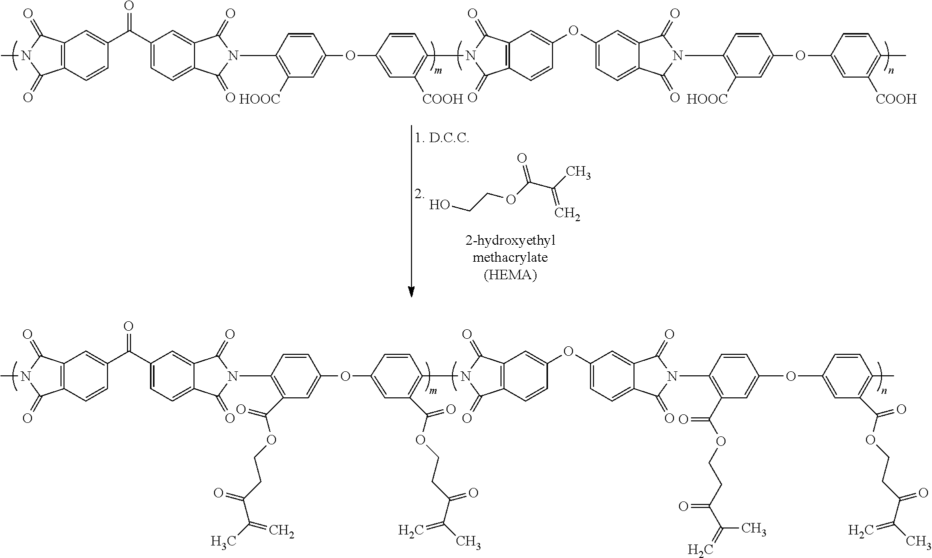

The acrylic monomer in the above reaction is 2-hydroxyethyl methacrylate (HEMA) and an additive of N,N′-dicyclohexylcarbodiimide (D.C.C.) is added in the above reaction. In the above reaction, all COOH functional groups of polyimide reacted with the acrylic monomers to bond the functional groups containing unsaturated double bonds to form a photosensitive polyimide. However, in a practical example, the bonding ratio of the COOH functional groups of polyimide bonded with the functional groups containing unsaturated double bonds will not reach 100%.

The OH or COOH functional groups that come from the diamine monomers are not all reacting with the acrylic monomers to bond the functional groups containing unsaturated double bonds, and thus X₂ may be a combination of:

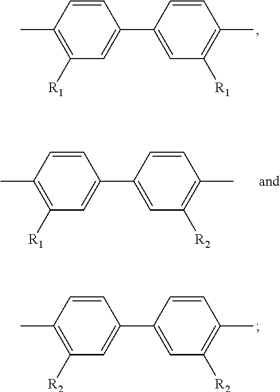

or a combination of:

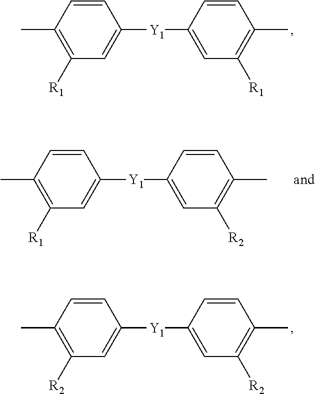

wherein Y₁ is one functional group selected from the functional groups below:
—O—, —CO—, —S—, —SO₂—, —C(CH₃)₂—, —C(CF₃)₂—, —(CH₂)ₙ₁—, —O(CH₂)ₙ₂O—, —COO(CH₂)ₙ₃OCO—,

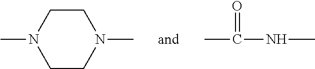

, wherein n1, n2 and n3 are an integer of 1 to 10; R₁ is OH or COOH; and R₂ is the functional group containing unsaturated double bonds which come from the OH or COOH functional groups reacted with acrylic monomer.

In the photosensitive polyimide of Formula (I), a bonding ratio of the OH or COOH functional groups bonded with the functional groups containing unsaturated double bonds has a preferred range. If the bonding ratio is too high, i.e. too many of the OH or COOH functional groups bonded with the functional groups containing unsaturated double bonds, only few of the OH or COOH functional groups remain. During a development process after an exposure process performed on a photoresist made from the photosensitive polyimide, an irradiated portion and an un-irradiated portion of the photoresist have almost the same degree of dissolution. Thus, the resolving power of dissolution of the photoresist after exposure is reduced and a pattern of the photoresist is difficult to develop.

Conversely, if the bonding ratio is too low, i.e. too few of the OH or COOH functional groups bonded with the functional groups containing unsaturated double bonds, many of the OH or COOH functional groups remain. Thus, the reactive crosslinking points of the photosensitive polyimide are too few. During a development process after an exposure process performed on a photoresist made from the photosensitive polyimide, an irradiated portion and an un-irradiated portion of the photoresist also have almost the same degree of dissolution. Thus, all of the photoresist is easily etched by the development solution and a pattern of the photoresist is difficult to obtain.

Therefore, in the photosensitive polyimide of Formula (I), the mole ratio of the repeated units containing R₂ functional group with unsaturated double bonds is preferably 15 mol % to 95 mol %, and more preferably 25 mol % to 85 mol % based on the total mole number of all repeated units in Formula (I).

In other words, in the photosensitive polyimide of Formula (I), the mole ratio of the repeated units containing

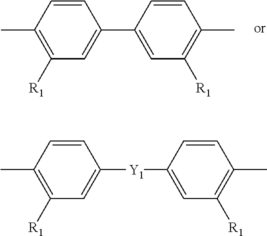

is preferably 5 mol % to 85 mol %, more preferably 15 mol % to 75 mol %; and the mole ratio of the repeated units containing

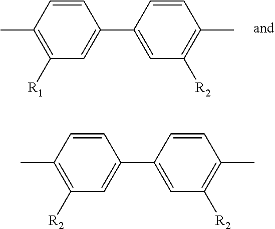

or the repeated units containing

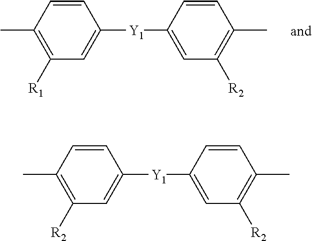

is preferably 15 mol % to 95 mol %, more preferably 25 mol % to 85 mol %, based on the total mole number of all repeated units in Formula (I).

Therefore, in the photosensitive polyimide of the present disclosure, the mole ratio of the repeated units containing R₂ functional group with unsaturated double bonds is 15 mol % to 95 mol % based on the total mole number of all repeated units in the photosensitive polyimide, i.e. the photosensitive polyimide of the present disclosure bonded with R₂ functional group containing unsaturated double bonds may have a bonding ratio of 15 mol % to 95 mol %.

According to an embodiment, the photosensitive polyimide of the present disclosure can be used to combine with a photocrosslinking agent and a photoinitiator to form a negative type photoresist composition. Based on 100 parts by weight of the photosensitive polyimide of the present disclosure, the photocrosslinking agent may be 20 to 150 parts by weight and the photoinitiator may be 0.01 to 20 parts by weight.

According to another embodiment, the photosensitive polyimide of the present disclosure having at least one kind of bonding ratio of R₂ functional group containing unsaturated double bonds can be used to mix with other non-photosensitive polyimide without functional group containing unsaturated double bonds and then to combine with a photocrosslinking agent and a photoinitiator to form a negative type photoresist composition. Based on a total weight of 100 parts by weight of the photosensitive polyimide of the present disclosure and the non-photosensitive polyimide, the photocrosslinking agent may be 20 to 150 parts by weight and the photoinitiator may be 0.01 to 20 parts by weight.

According to another embodiment, the photosensitive polyimide of the present disclosure having at least two kinds of bonding ratios of R₂ functional group containing unsaturated double bonds can be used to mix together for forming a negative type photoresist composition. For example, a photosensitive polyimide of the present disclosure having a higher bonding ratio of R₂ functional group containing unsaturated double bonds is mixed with another photosensitive polyimide of the present disclosure having a lower bonding ratio of R₂ functional group containing unsaturated double bonds to form a photosensitive polyimide having a proper bonding ratio of R₂ functional group containing unsaturated double bonds. Then, the photosensitive polyimide having the proper bonding ratio of R₂ functional group containing unsaturated double bonds is used to combine with a photocrosslinking agent and a photoinitiator to form a negative type photoresist composition. Based on a total weight of 100 parts by weight of all the photosensitive polyimide, the photocrosslinking agent may be 20 to 150 parts by weight and the photoinitiator may be 0.01 to 20 parts by weight.

The photocrosslinking agent may be a single molecule containing two or more than two unsaturated double bonds. The photocrosslinking agent has a function of reacting with the double bonds of the photosensitive polyimide to increase the degree of crosslinking between the photosensitive polyimide. If too much of the photocrosslinking agent is added, the degree of crosslinking between the photosensitive polyimide will be too high. Thus, the resolving power of dissolutions between an irradiated portion and an un-irradiated portion of a photoresist made from the negative type photoresist composition is too low. Moreover, the photocrosslinking agent is usually a small molecule. If too much of the photocrosslinking agent is added, the properties of the photoresist made thereby is reduced. Thus, the high heat resistance and high electric insulativity of the photosensitive polyimide in the photoresist will not manifest. If too little of the photocrosslinking agent is added, the degree of crosslinking between the photosensitive polyimide cannot be enhanced. Thus, the resolving power of dissolutions between an irradiated portion and an un-irradiated portion of the photoresist also cannot be enhanced. Accordingly, based on 100 parts by weight of all the photosensitive polyimide, the photocrosslinking agent is preferably added in 20 to 150 parts by weight.

The photoinitiator has the function of producing free radicals after irradiation to react with double bonds of the photosensitive polyimide and thus make the double bonds of the photosensitive polyimide produce a crosslinking reaction. The photoinitiator of the negative type photoresist composition of the present disclosure is not limited to any kind of photoinitiator. Generally, the photoinitiator can absorb light in a wavelength of 200 nm-500 nm to produce free radicals. Based on 100 parts by weight of photosensitive polyimide, the photoinitiator is preferably added in 0.01 to 20 parts by weight, and more preferably added in 0.5 to 10 parts by weight. If too little of the photoinitiator is added, the negative type photoresist composition will have a poor photosensitivity and thus it is difficult to produce a crosslinking reaction while the exposure process is performed thereon. If too much of the photoinitiator is added, the surface of the photoresist will absorb a major amount of light while the exposure process is performed thereon. Thus, it is difficult for the light to reach the bottom of the photoresist. It causes the degrees of crosslinking and the degrees of dissolution at the surface and the bottom of the photoresist to be different. Thus, it produces ill effects to the end development process of line.

In addition, based on 100 parts by weight of the photosensitive polyimide, the negative type photoresist composition of the present disclosure may further include less than 20 parts by weight of other additional additives. The additional additives comprise a photo-initiation catalyst, a defoaming agent, an antioxidant, a flame retardant, a leveling agent, an adhesion promoter, or a combination thereof. The additional additives have the function of improving the physical and chemical properties of the negative type photoresist composition. However, if too much of the additional additives are added, the properties of the negative type photoresist composition will be influenced. If too little of the additional additives are added, the functions of the additional additives will not appear.

The photosensitive polyimide of the present disclosure and the fabrication method thereof are described in detail below with several Examples and Comparative Examples, and the results of several negative type photoresist compositions made from the photosensitive polyimide of the Examples and the Comparative Examples after an exposure and development process are also described in detail below:

### Example 1

At room temperature, N₂ was introduced into a three-necked bottle, and two kinds of diamine monomers of 17.3 g of 3,3′-dihydroxy-4,4′-diamino-biphenyl (HAB) and 8.2 g of 2,2-bis[4-(4-aminophenoxy)phenyl]propane (BAPP), and 0.3 g of a catalyst of isoquinoline were dissolved in 320 g of a solvent of N-methylpyrrolidone (NMP). After the diamine monomers were completely dissolved, two kinds of dianhydride monomers of 16.1 g of 3,3′,4,4′-benzophenone tetracarboxylic dianhydride (BTDA) and 14.7 g of 3,3′,4,4′-biphenyl tetracarboxylic dianhydride (BPDA) were added. After the dianhydride monomers were completely dissolved, it was continuously stirred for one hour to form a sticky polyimide (PI) solution. Then, the polyimide (PI) solution was heated to 220° C. to react for three hours. During the reaction process, water was removed by a water-removal device.

After the reaction was completed, the polyimide (PI) solution was cooled down to room temperature, and 16.2 g of triethylamine (TEA) was added, stirring for 30 minutes at room temperature. In an ice bath, 14.5 g of an acrylic monomer of acryloyl chloride (AC) was dripped slowly and then allowed to react for 8 hours at room temperature. After the reaction was completed, through filtering, re-precipitating with ethanol, and drying, a photosensitive polyimide of Example 1 was obtained. Then, the photosensitive polyimide of Example 1 was analyzed by a nuclear magnetic resonance (NMR) spectrometer. The bonding ratio of unsaturated double bonds on the photosensitive polyimide of Example 1 was about 50 mol %.

### Example 2

At room temperature, N2 was introduced into a three-necked bottle, one kind of a diamine monomer of 21.6 g of 3,3′-dihydroxy-4,4′-diamino-biphenyl (HAB), and 0.3 g of a catalyst of isoquinoline were dissolved in 284 g of a solvent of N-methylpyrrolidone (NMP). After the diamine monomer was completely dissolved, two kinds of dianhydride monomers of 16.1 g of 3,3′,4,4′-benzophenone tetracarboxylic dianhydride (BTDA) and 12.4 g of bicyclo[2.2.2]oct-7-ene-2,3,5,6-tetracarboxylic dianhydride (B1317) were added. After the dianhydride monomers were completely dissolved, continuous stirring for one hour formed a sticky polyimide (PI) solution. Then, the polyimide (PI) solution was heated to 220° C. to react for three hours. During the reaction process, water was removed by a water-removal device.

After the reaction was completed, the polyimide (PI) solution was cooled down to room temperature, and 10.1 g of triethylamine (TEA) was added, stirring for 30 minutes at room temperature. In an ice bath, 9.05 g of an acrylic monomer of acryloyl chloride (AC) was dripped slowly and then underwent a reaction for 8 hours at room temperature. After the reaction was completed, through filtering, re-precipitating with ethanol, and drying, the photosensitive polyimide of Example 2 was obtained. Then, the photosensitive polyimide of Example 2 was analyzed by a nuclear magnetic resonance (NMR) spectrometer. The bonding ratio of unsaturated double bonds on the photosensitive polyimide of Example 2 was about 35 mol %.

### Example 3

At room temperature, N2 was introduced into a three-necked bottle, and one kind of a diamine monomer of 28.6 g of methylene bis(anthranilic acid) (MBAA) diamine, and 0.3 g of a catalyst of isoquinoline were dissolved in 324 g of a solvent of N-methyl pyrrolidone (NMP). After the diamine monomer was completely dissolved, two kinds of dianhydride monomers of 16.1 g of 3,3′,4,4′-benzophenone tetracarboxylic dianhydride (BTDA) and 12.4 g of bicyclo[2.2.2]oct-7-ene-2,3,5,6-tetracarboxylic dianhydride (B1317) were added. After the dianhydride monomers were completely dissolved, continuous stirring for one hour formed a sticky polyimide (PI) solution. Then, the polyimide (PI) solution was heated to 220° C. to react for three hours. During the reaction process, water was removed by a water-removal device.

After the reaction was completed, the polyimide (PI) solution was cooled down to room temperature, and 50 g of N,N′-dicyclohexylcarbodiimide (D.C.C.) was added, stirring for 30 minutes at room temperature. In an ice bath, 26 g of an acrylic monomer of 2-hydroxyethyl methacrylate (HEMA) was dripped slowly and then allowed to react for 8 hours at room temperature. After the reaction was completed, through filtering, re-precipitating with ethanol, and drying, the photosensitive polyimide of Example 3 was obtained. Then, the photosensitive polyimide of Example 3 was analyzed by a nuclear magnetic resonance (NMR) spectrometer. The bonding ratio of unsaturated double bonds onto the photosensitive polyimide of Example 3 was about 80 mol %.

### Example 4

At room temperature, N2 was introduced into a three-necked bottle, and one kind of a diamine monomer of 21.6 g of 3,3′-dihydroxy-4,4′-diamino-biphenyl (HAB), and 0.3 g of a catalyst of isoquinoline were dissolved in 284 g of a solvent of N-methyl pyrrolidone (NMP). After the diamine monomer was completely dissolved, two kinds of dianhydride monomers of 16.1 g of 3,3′,4,4′-benzophenone tetracarboxylic dianhydride (BTDA) and 12.4 g of bicyclo[2.2.2]oct-7-ene-2,3,5,6-tetracarboxylic dianhydride (B1317) were added. After the dianhydride monomers were completely dissolved, continuous stirring for one hour formed a sticky polyimide (PI) solution. Then, the polyimide (PI) solution was heated to 220° C. to react for three hours. During the reaction process, water was removed by a water-removal device.

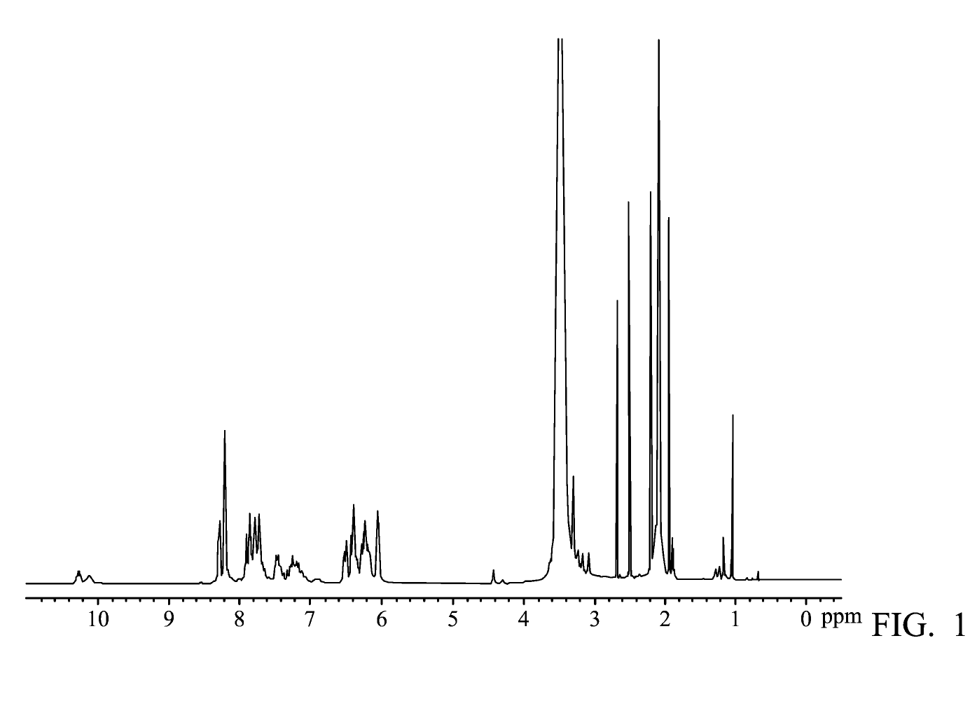

After the reaction was completed, the polyimide (PI) solution was cooled down to room temperature, and 20.2 g of triethylamine (TEA) was added, stirring for 30 minutes at room temperature. In an ice bath, 18.1 g of an acrylic monomer of acryloyl chloride (AC) was dripped slowly and then reacted for 8 hours at room temperature. After the reaction was completed, through filtering, re-precipitating with ethanol, and drying, the photosensitive polyimide of Example 4 was obtained. Then, the photosensitive polyimide of Example 4 was analyzed by a nuclear magnetic resonance (NMR) spectrometer. The NMR spectrum of the photosensitive polyimide of Example 4 is shown in FIG. 1. Calculations of the peak area at 8-8.5 ppm and the peak area at 10-10.5 ppm show that the bonding ratio of unsaturated double bonds on the photosensitive polyimide of Example 4 was about 93 mol %.

### Example 5

At room temperature, N2 was introduced into a three-necked bottle, and one kind of a diamine monomer of 21.6 g of 3,3′-dihydroxy-4,4′-diamino-biphenyl (HAB), and 0.3 g of a catalyst of isoquinoline were dissolved in 284 g of a solvent of N-methyl pyrrolidone (NMP). After the diamine monomer was completely dissolved, two kinds of dianhydride monomers of 16.1 g of 3,3′,4,4′-benzophenone tetracarboxylic dianhydride (BTDA) and 12.4 g of bicyclo[2.2.2]oct-7-ene-2,3,5,6-tetracarboxylic dianhydride (B1317) were added. After the dianhydride monomers were completely dissolved, continuous stirring for one hour formed a sticky polyimide (PI) solution. Then, the polyimide (PI) solution was heated to 220° C. to react for three hours. During the reaction process, water was removed by a water-removal device.

11.1 g of the polyimide (PI) solution was mixed with 1.9 g of the photosensitive polyimide powder of Example 4 to obtain a photosensitive polyimide solution of Example 5. The photosensitive polyimide solution of Example 5 was analyzed by the same method as Examples 1-4. The bonding ratio of unsaturated double bonds on the photosensitive polyimide solution of Example 5 was about 55 mol %.

### Comparative Example 1

At room temperature, N2 was introduced into a three-necked bottle, and two kinds of diamine monomers of 17.3 g of 3,3′-dihydroxy-4,4′-diamino-biphenyl (HAB) and 8.2 g of 2,2-bis[4-(4-aminophenoxy)phenyl]propane (BAPP), and 0.3 g of a catalyst of isoquinoline were dissolved in 320 g of a solvent of N-methylpyrrolidone (NMP). After the diamine monomers were completely dissolved, two kinds of dianhydride monomers of 16.1 g of 3,3′,4,4′-benzophenone tetracarboxylic dianhydride (BTDA) and 14.7 g of 3,3′,4,4′-biphenyl tetracarboxylic dianhydride (BPDA) were added. After the dianhydride monomers were completely dissolved, continuous stirring for one hour formed a sticky polyimide (PI) solution. Then, the polyimide (PI) solution was heated to 220° C. to react for three hours. During the reaction process, water was removed by a water-removal device.

After the reaction was completed, the polyimide (PI) solution was cooled down to room temperature, and 8.1 g of triethylamine (TEA) was added, stirring for 30 minutes at room temperature. In an ice bath, 7.3 g of an acrylic monomer of acryloyl chloride (AC) was dripped slowly and then reacted for 8 hours at room temperature. After the reaction was completed, through filtering, re-precipitating with ethanol, and drying, the photosensitive polyimide of Comparative Example 1 was obtained. Then, the photosensitive polyimide of Comparative Example 1 was analyzed by a nuclear magnetic resonance (NMR) spectrometer. The bonding ratio of unsaturated double bonds on the photosensitive polyimide of Comparative Example 1 was about 100 mol %.

### Comparative Example 2

At room temperature, N2 was introduced into a three-necked bottle, and one kind of a diamine monomer of 41 g of 2,2-bis[4-(4-aminophenoxy)phenyl]propane (BAPP), and 0.3 g of a catalyst of isoquinoline were dissolved in 394 g of a solvent of N-methyl pyrrolidone (NMP). After the diamine monomer was completely dissolved, two kinds of dianhydride monomers of 16.1 g of 3,3′,4,4′-benzophenone tetracarboxylic dianhydride (BTDA) and 12.4 g of bicyclo[2.2.2]oct-7-ene-2,3,5,6-tetracarboxylic dianhydride (B1317) were added. After the dianhydride monomers were completely dissolved, continuous stirring for one hour formed a sticky polyimide (PI) solution. Then, the polyimide (PI) solution was heated to 220° C. to react for three hours. During the reaction process, water was removed by a water-removal device.

After the reaction was completed, the polyimide (PI) solution was cooled down to room temperature, re-precipitating with ethanol, and drying, a polyimide of Comparative Example 2 was obtained. The polyimide of Comparative Example 2 has a bonding ratio of unsaturated double bonds of 0 mol %.

[Negative Type Photoresist Compositions Made from the Polyimide of Various Examples and Comparative Examples and Results Thereof after an Exposure and Development Process]

2 g of the photosensitive polyimide of Examples 1-4 individually, 2 g of the polyimide of Comparative Examples 1-2 individually, and 13 g of the photosensitive polyimide solution of Example 5 were individually dissolved in 10 g of a solvent of N-methyl pyrrolidone (NMP). Then, 0.3 g of a photoinitiator and 2 g of a photocrosslinking agent of tri(ethylene glycol) diacrylate were added together, stirring uniformly to obtain various negative type photoresist compositions. Next, the negative type photoresist composition was coated onto a glass plate by a spin coating method to form a photoresist film with a thickness of about 15 μm. After an exposure process, the photoresist film was developed with a NaOH aqueous solution of a PH value of 11. The development results are shown in Table 1 below:

TABLE 1
Compositions of the polyimide of various Examples and Comparative
Examples and the development results thereof.

| | | | | | | Compar- | Compar- |
|---|---|---|---|---|---|---|---|
| | | | | | | ative | rative |
| | Example | Example | Example | Example | Example | Example | Example |
| | 1 | 2 | 3 | 4 | 5 | 1 | 2 |
| dianhydride | BTDA | BTDA | BTDA | BTDA | BTDA | BTDA | BTDA |
| | BPDA | B1317 | B1317 | B1317 | B1317 | BPDA | B1317 |
| diamine | HAB | HAB | MBAA | HAB | HAB | HAB | BAPP |
| | BAPP | | | | | BAPP | |
| Bonding ratio of | 50 | 35 | 80 | 93 | 55 | 10 | 0 |
| unsaturated double | | | | | | | |
| bonds (mol %) | | | | | | | |
| Whether obtain a | Yes | Yes | Yes | Yes | Yes | No | No |
| pattern with a line | | | | | | | |
| width of 100 μm by a | | | | | | | |
| development with a | | | | | | | |
| NaOH aqueous | | | | | | | |
| solution of a PH value | | | | | | | |
| of 11 | | | | | | | |

As shown in the results in Table 1, the photoresists made from the photosensitive polyimide of Examples 1-5 can obtain a pattern with a line width of about 100 μm after performing an exposure and development process. If a preferable photoinitiator, a preferable crosslinking agent, and a preferable photosensitivity promoter are added to the negative type photoresist compositions, a pattern with a fine line width of about 10 μm will be obtained. However, the photoresists made from the polyimide of Comparative Examples 1-2 cannot obtain a pattern after the exposure and development process. Therefore, the photoresists made from the photosensitive polyimide of the present disclosure have better effect on exposure and development.

Moreover, the bonding ratio of unsaturated double bonds in the photosensitive polyimide of Example 4 can reach about 93 mol %. It shows the chemical structure design of the photosensitive polyimide of the present disclosure can be bonded with a much higher mole ratio of functional groups containing unsaturated double bonds. That has the benefit of enhancing the photosensitivity of the photosensitive polyimide.

In addition, the photosensitive polyimide of Example 5 having a bonding ratio of unsaturated double bonds of about 55 mol % is obtained from mixing the photosensitive polyimide of Example 4 having a bonding ratio of unsaturated double bonds of about 93 mol % with a non-photosensitive polyimide which does not have functional groups containing unsaturated double bonds (having a bonding ratio of unsaturated double bonds of 0 mol %). Thus, photosensitive polyimide with various bonding ratios of unsaturated double bonds can be obtained by various addition ratios of two photosensitive polyimides with different bonding ratios of unsaturated double bonds. According to the present disclosure, use of a photosensitive polyimide having only one kind of bonding ratio of unsaturated double bonds to mix with another non-photosensitive polyimide having a bonding ratio of unsaturated double bonds of 0 mol %; or use of photosensitive polyimides having more than one kind of bonding ratio of unsaturated double bonds to mix together, a photosensitive polyimide having various required kinds of bonding ratios of unsaturated double bonds is obtained. In which, a photoresist made from a photosensitive polyimide having a bonding ratio of unsaturated double bonds in a range of 30 mol % to 80 mol % has a preferable development effect.

While the disclosure has been described by way of example and in terms of preferred embodiment, it is to be understood that the disclosure is not limited thereto. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A photosensitive polyimide of Formula (I): 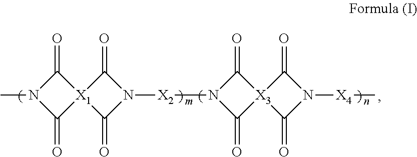
wherein X₁ and X₃ are the same or different organic functional groups having four covalent bonds;
X₂ and X₄ are the same or different organic functional groups having two covalent bonds, and wherein X₂ is a combination of: 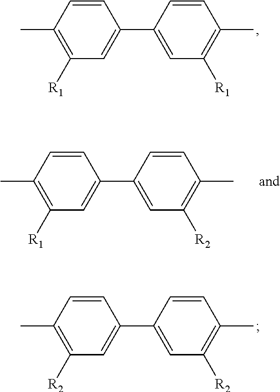
or a combination of: 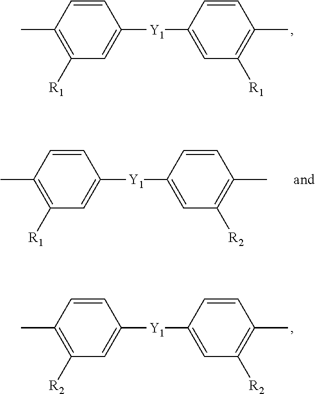
wherein Y₁ is selected from a group consisting of:
—O—, —CO—, —S—, —SO₂—, —C(CH₃)₂—, —C(CF₃)₂—, —(CH₂)ₙ₁—, —O(CH₂)ₙ₂O—, —COO(CH₂)ₙ₃OCO—, 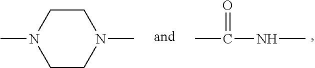
wherein n1, n2 and n3 are an integer of 1 to 10;
R₁ is OH or COOH;
R₂ is selected from a group consisting of: 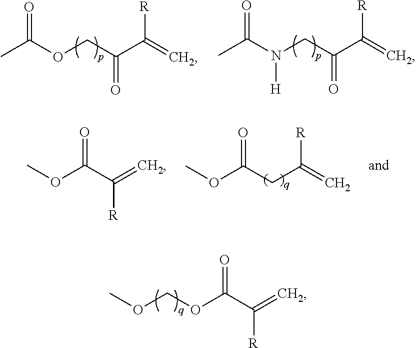
wherein R is H or CH₃, p is an integer of 1 to 20, and q is an integer of 1 to 20; and
m and n in Formula (I) are the number of repeated units, wherein m is an integer of 10 to 1000, and n is an integer of 10 to 1000.

2. The photosensitive polyimide as claimed in claim 1, wherein X₁ and X₃ are individually selected from a group consisting of:

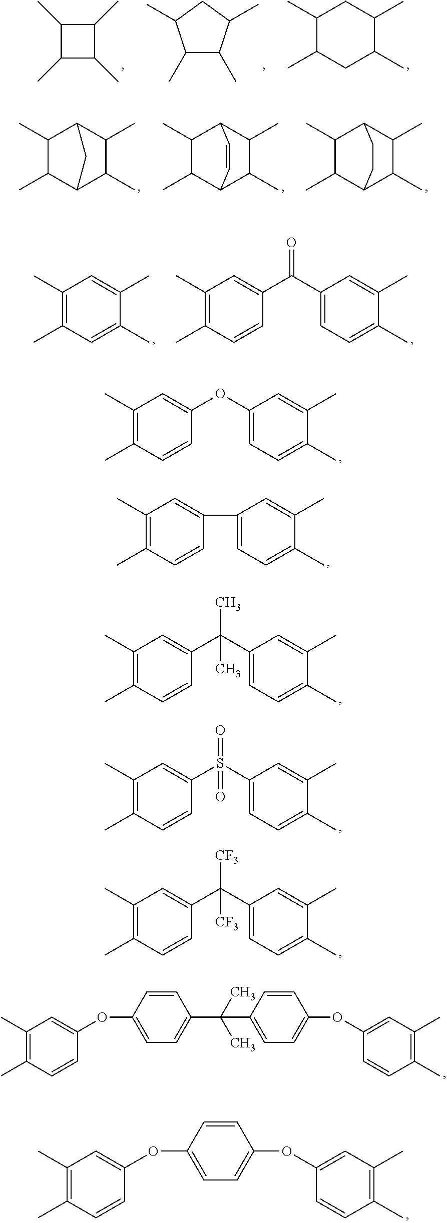

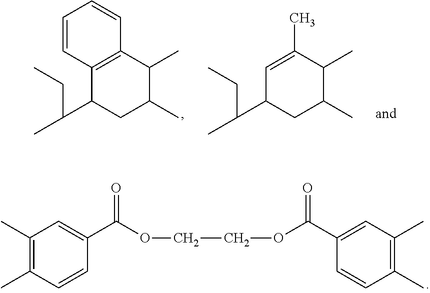

3. The photosensitive polyimide as claimed in claim 1, wherein X₄ is different from X₂, and X₄ is selected from a group consisting of: 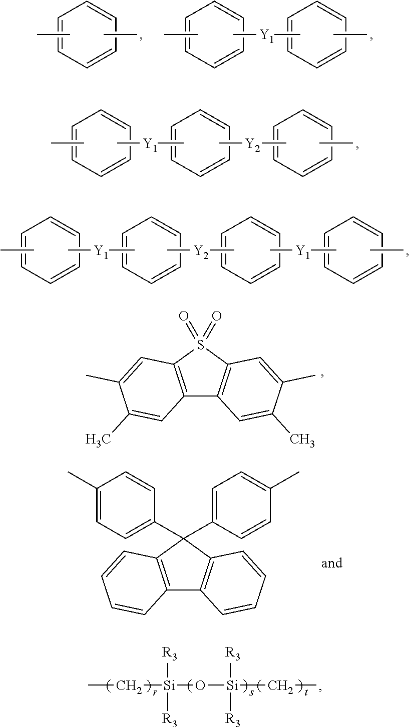
wherein Yₜ and Y₂ are the same or different organic functional groups having two covalent bonds, and Y₁ and Y₂ are individually selected from a group consisting of:
—O—, —CO—, —S—, —SO₂—, —C(CH₃)₂—, —C(CF₃)₂—, —(CH₂)ₙ₁—, —O(CH₂)ₙ₂O—, —COO(CH₂)ₙ₃OCO—, 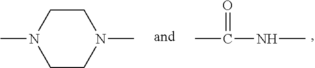
wherein n1, n2 and n3 are an integer of 1 to 10;
R₃ is hydrogen, methyl, ethyl or phenyl; and
r, s, t are an integer of 1 to 30.

4. The photosensitive polyimide as claimed in claim 3, wherein the mole ratio of the repeated units containing X₂ is 20 mol % to 85 mol %, and the mole ratio of the repeated units containing X₄ is 15 mol % to 80 mol % based on the total mole number of all repeated units in Formula (I).

5. The photosensitive polyimide as claimed in claim 1, wherein the mole ratio of the repeated units containing 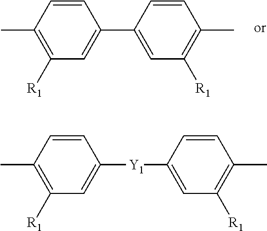
is 5 mol % to 85 mol %, and the mole ratio of the repeated units containing 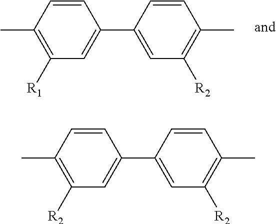
or the repeated units containing 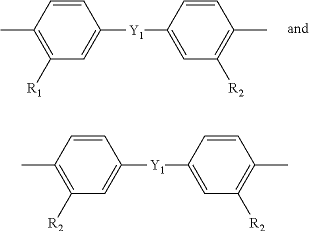
is 15 mol % to 95 mol % based on the total mole number of all repeated units in Formula (I).

6. A negative type photoresist composition, comprising:
100 parts by weight of a photosensitive polyimide;
20 to 150 parts by weight of a photocrosslinking agent; and
0.01 to 20 parts by weight of a photoinitiator
, wherein the photosensitive polyimide at least includes a photosensitive polyimide of Formula (I): 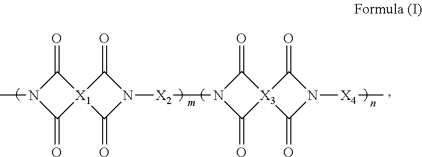
wherein X₁ and X₃ are the same or different organic functional groups having four covalent bonds;
X₂ and X₄ are the same or different organic functional groups having two covalent bonds, and wherein X₂ is a combination of: 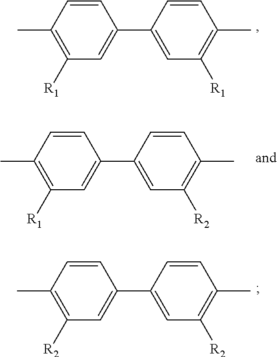
or a combination of: 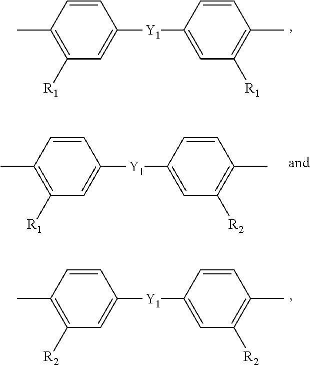
wherein Y₁ is selected from a group consisting of:
—O—, —CO—, —S—, —SO₂—, —C(CH₃)₂—, —C(CF₃)₂—, —(CH₂)ₙ₁—, —O(CH₂)ₙ₂O—, —COO(CH₂)ₙ₃OCO—, 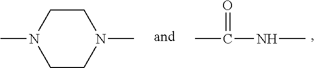
wherein n1, n2 and n3 are an integer of 1 to 10;
R₁ is OH or COOH;
R₂ is selected from a group consisting of: 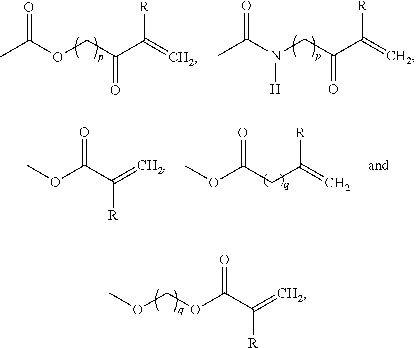
wherein R is H or CH₃, p is an integer of 1 to 20, and q is an integer of 1 to 20; and
m and n in Formula (I) are the number of repeated units, wherein m is an integer of 10 to 1000, and n is an integer of 10 to 1000.

7. The negative type photoresist composition as claimed in claim 6, wherein X₁ and X₃ in the photosensitive polyimide of Formula (I) are individually selected from a group consisting of:

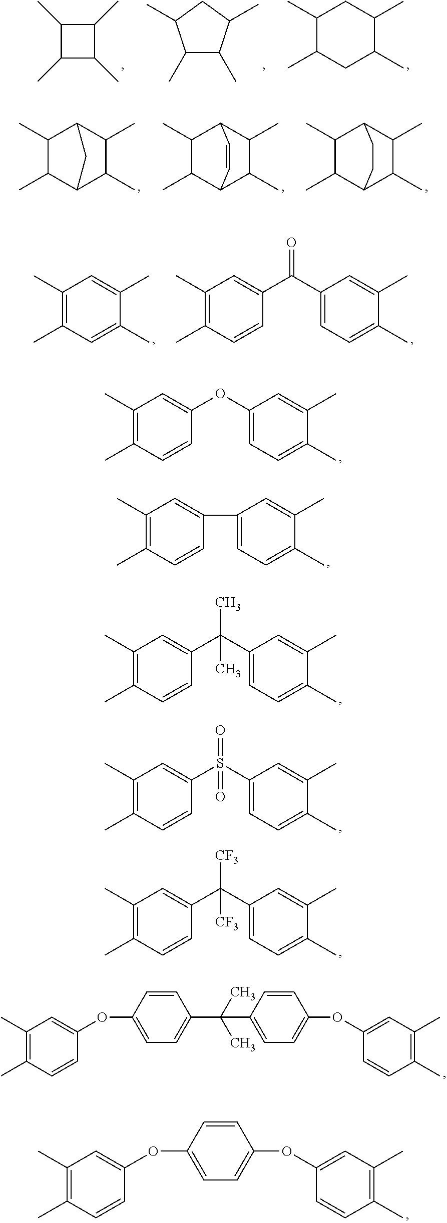

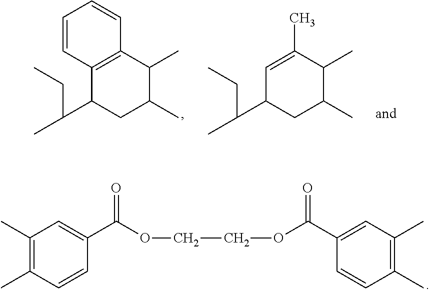

8. The negative type photoresist composition as claimed in claim 6, wherein X₄ and X₂ in the photosensitive polyimide of Formula (I) are different from each other, and X₄ is selected from a group consisting of: 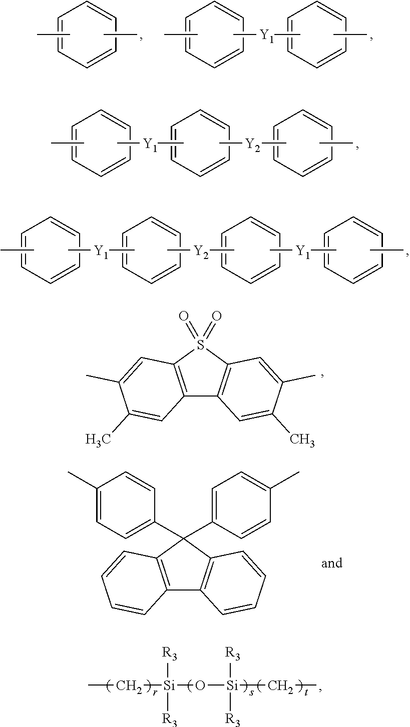
wherein Y₁ and Y₂ are the same or different organic functional groups having two covalent bonds, and Y₁ and Y₂ are individually selected from a group consisting of:
—O—, —CO—, —S—, —SO₂—, —C(CH₃)₂—, —C(CF₃)₂—, —(CH₂)ₙ₁—, —O(CH₂)ₙ₂O—, —COO(CH₂)ₙ₃OCO—, 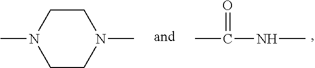
wherein n1, n2 and n3 are an integer of 1 to 10;
R₃ is hydrogen, methyl, ethyl, or phenyl; and
r, s, t are an integer of 1 to 30.

9. The negative type photoresist composition as claimed in claim 8, wherein the mole ratio of the repeated units containing X₂ is 20 mol % to 85 mol %, and the mole ratio of the repeated units containing X₄ is 15 mol % to 80 mol % based on the total mole number of all repeated units in the photosensitive polyimide of Formula (I).

10. The negative type photoresist composition as claimed in claim 6, wherein the mole ratio of the repeated units containing 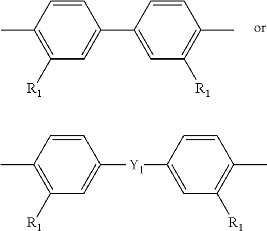
is 5 mol % to 85 mol %, and the mole ratio of the repeated units containing 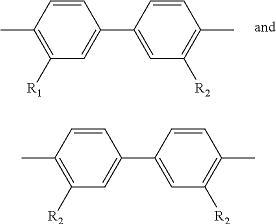
or the repeated units containing 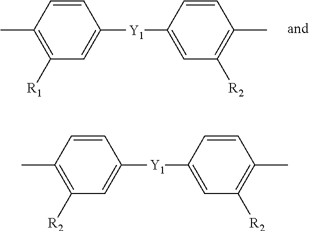
is 15 mol % to 95 mol % based on the total mole number of all repeated units in the photosensitive polyimide of Formula (I).

11. The negative type photoresist composition as claimed in claim 6, wherein the photosensitive polyimide is a mixture, and the mixture includes a non-photosensitive polyimide and the photosensitive polyimide of Formula (I).

12. The negative type photoresist composition as claimed in claim 11, wherein the mole ratio of the repeated units containing the functional group of R₂ is 30 mol % to 80 mol % based on the total mole number of all repeated units in the non-photosensitive polyimide and the photosensitive polyimide of Formula (I).

13. The negative type photoresist composition as claimed in claim 6, wherein the photosensitive polyimide is a mixture, and the mixture includes two or more than two kinds of the photosensitive polyimide of Formula (I), wherein the two or more kinds of the photosensitive polyimide of Formula (I) individually have different mole ratios of the repeated units containing the functional group of R₂.

14. The negative type photoresist composition as claimed in claim 13, wherein the mole ratios of the repeated units containing the functional group of R₂ in the two or more kinds of the photosensitive polyimide of Formula (I) is 30 mol % to 80 mol % based on the total mole number of all repeated units in the two or more kinds of the photosensitive polyimide of Formula (I).

15. The negative type photoresist composition as claimed in claim 6, wherein the chemical structure of the photocrosslinking agent is a single molecule containing two or more than two unsaturated double bonds.

16. The negative type photoresist composition as claimed in claim 6, wherein the photoinitiator absorbs light in a wavelength of 200 nm-500 nm to produce free radicals.

17. The negative type photoresist composition as claimed in claim 6, further comprising an additional additive, wherein the additional additive comprises a photo-initiation catalyst, a defoaming agent, an antioxidant, a flame retardant, a leveling agent, an adhesion promoter or a combination thereof.
